(19) United States
(12) Patent Application Publication
(10) Pub. No.: US 2022/0415920 A1
(43) Pub. Date: Dec. 29, 2022

(54) SEMICONDUCTOR MEMORY DEVICE

(71) Applicant: Kioxia Corporation, Tokyo (JP)

(72) Inventors: Shuto YAMASAKA, Mie (JP); Tomonori AOYAMA, Yokkaichi (JP)

(73) Assignee: Kioxia Corporation, Tokyo (JP)

(21) Appl. No.: 17/897,843

(22) Filed: Aug. 29, 2022

Related U.S. Application Data
(62) Division of application No. 16/123,133, filed on Sep. 6, 2018.

(30) Foreign Application Priority Data
Mar. 20, 2018 (JP) 2018-052456

(51) Int. Cl. H01L 27/11582; H01L 27/11573; H01L 27/1157

(52) U.S. Cl. CPC H01L 27/11582; H01L 27/11573; H01L 27/1157

(57) ABSTRACT

According to one embodiment, a semiconductor memory device includes a circuitry layer, first conductive layers, a pillar layer, and a second conductive layer. The circuitry layer is provided on a substrate and includes a CMOS circuit. The first conductive layers are provided above the circuitry layer, and are stacked with an insulation layer interposed therebetween. The pillar layer crosses the first conductive layers, and includes silicon single crystal. The second conductive layer is provided on the pillar layer and includes silicon single crystal containing impurities. The first conductive layers are provided between the circuitry layer and the second conductive layer.

### CROSS-REFERENCE TO RELATED APPLICATIONS

This application is a divisional application of U.S. application Ser. No. 16/123,133, filed on Sep. 6, 2018, which is based upon and claims the benefit of priority from the Japanese Patent Application No. 2018-052456, filed Mar. 20, 2018, the entire contents of which are incorporated herein by reference.

### FIELD

Embodiments described herein relate generally to a semiconductor memory device.

### BACKGROUND

A NAND flash memory, in which memory cells are three-dimensionally stacked, has been known as a semiconductor memory device.

### BRIEF DESCRIPTION OF THE DRAWING

FIG. 1 is a schematic perspective view of a semiconductor memory device according to embodiments.

FIG. 2 is a cross section of a memory cell array according to the embodiments.

FIG. 3 is a cross section of a semiconductor memory device according to a first embodiment.

FIGS. 4 to 14 are cross sections of the structure, representing processes of a method for manufacturing the semiconductor memory device according to the first embodiment.

FIGS. 15 to 21 are cross sections showing modification examples of the manufacturing method according to the first embodiment.

FIG. 22 is a cross section of a semiconductor memory device according to a second embodiment.

FIG. 23 is a cross section of the structure, representing a process of a method for manufacturing the semiconductor memory device according to the second embodiment.

### DETAILED DESCRIPTION

In general, according to one embodiment, a semiconductor memory device includes a circuitry layer, first conductive layers, a pillar layer, and a second conductive layer. The circuitry layer is provided on a substrate and includes a CMOS circuit. The first conductive layers are provided above the circuitry layer, and are stacked with an insulation layer interposed therebetween. The pillar layer crosses the first conductive layers, and includes silicon single crystal. The second conductive layer is provided on the pillar layer and includes silicon single crystal containing impurities. The first conductive layers are provided between the circuitry layer and the second conductive layer.

The embodiments of the present invention will be explained with reference to the drawings. In the following explanation, components having the same functions and structures will be referred to by the same reference numerals. The embodiments are described to give examples of apparatuses and methods that realize the technical concepts of the embodiments.

### [1] FIRST EMBODIMENT

A semiconductor memory device according to a first embodiment will be discussed. Here, as an example of a semiconductor memory device, a three-dimensionally stacked NAND flash memory in which memory cell transistors (hereinafter also referred to as memory cells) are stacked above the semiconductor substrate will be considered. Irs the following description, “coupling” represents not only components being directly coupled to each other, but also components being coupled to each other with another component interposed therebetween.

### [1-1] Structure of Semiconductor Memory Device

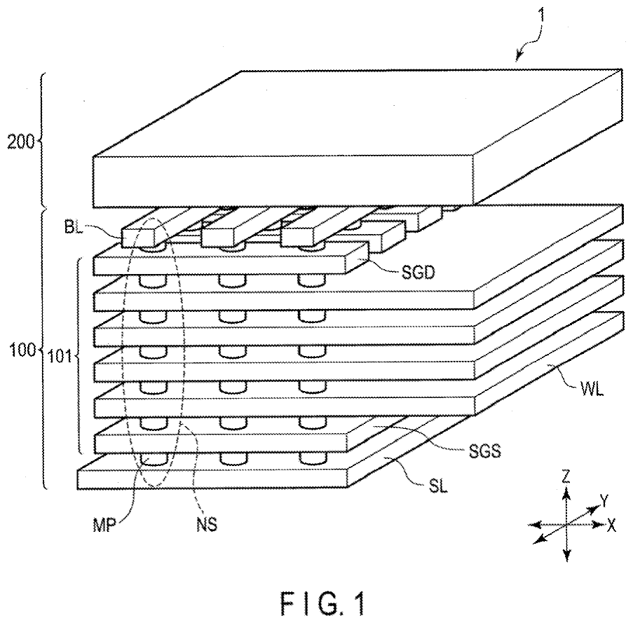

FIG. 1 is a schematic perspective view of the semiconductor memory device according to the first embodiment. To simplify and facilitate visualization, interlayer insulation layers, insulation/isolation films, and a hookup region for hooking up word lines are omitted from FIG. 1. In FIG. 1, two directions that are orthogonal to each other and are both parallel to the surface of the semiconductor substrate are referred to as X and Y directions. The direction orthogonal to these X and Y directions (X-Y surface), in which a plurality of conductive layers (word lines WL) are stacked, is referred to as the Z direction (layer stacking direction).

As illustrated in FIG. 1, a semiconductor memory device 1 includes a memory chip 100 including a memory cell array in which memory cells are three-dimensionally stacked, and a circuitry chip (circuitry layer) 200 including peripheral circuit configured to control the writing, reading, and erasing of data with respect to the memory cells. The semiconductor memory device 1 has a structure in which the memory chip 100 and the circuitry chip 200 are bonded to each other. The memory cell array includes a plurality of NANO strings NS, in each of which memory cells are stacked in the Z direction.

The structure of the memory chip 100 is explained below. A source-side select gate line SGS, a plurality of word lines WL, a drain-side select gate line SGD, and bit lines BL are provided in this order above a source line SL with insulation layers (not shown) interposed therebetween.

Specifically, a layer of the source-side select gate line SGS is provided on the source line SL layer, with an insulation layer (not shown) interposed therebetween. An insulation layer (not shown) is provided on the source-side select gate line SGS, and on this insulation layer, the word lines WL and the insulation layers (not shown) are alternately stacked. An insulation layer (not. shown) is provided on the word line WL that is positioned the furthest from the source line SL, and on this insulation layer, a layer of the drain-side select gate lines SGD is provided. In this manner, a stacked body 101 in which the source-side select gate line SGS, the plurality of word lines WL, the drain-side select gate line SGD and the plurality of insulation layers (not shown) are stacked is provided.

Column-like memory pillars (or pillar layers) MP are provided in the stacked body 101 to extend in the Z direction. One end of each memory pillar MP is coupled to the source line SL, and the other end of the memory pillar MP is coupled to the bit lines BL. That is, the memory pillars MP extend from the source line SL through the source-side select gate line SGS, the word lines WL, the insulation layers, and the drain-side select gate line SGD, reaching the bit lines BL. The memory pillars MP will be discussed later in detail.

The word lines WL and the drain-side select gate line SGD extend in the X direction, while the bit lines BL extend in the Y direction.

### [1-1-1] Cross-Section Structure of Memory Cell Array

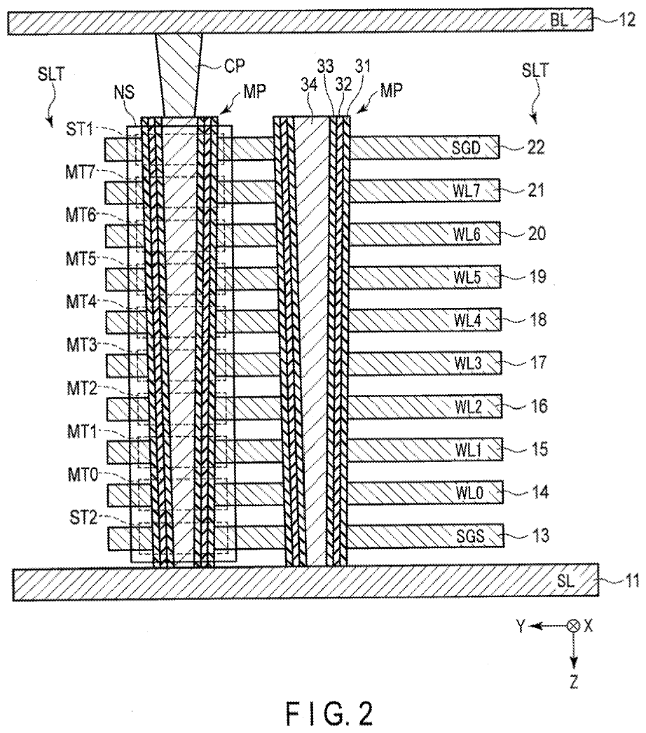

Next, the structure of a memory cell array included in the memory chip 100 according to the first embodiment will be explained in detail with reference to FIG. 2. FIG. 2 is a cross section of the memory cell array, taken along the Y direction.

The memory cell array includes a plurality of NAND strings NS provided in the stacked body 101. One end of each NAND string NS is coupled to the conductive layer (source line SL) 11, while the other end of the NAND string NS is coupled to the conductive layer (bit line BL) 12 with a contact plug CP interposed therebetween.

The stacked body 101 is provided, as illustrated in FIG. 2, between adjacent two slits SLT. The stacked body 101 includes a conductive layer (source-side select gate line SGS) 13, conductive layers (word lines WL0 to WL7) 14 to 21, a conductive layer (drain-side select gate lines SGD) 22, and memory pillars MP that extend through the conductive layers 13 to 22. The slits SLT extend in the X direction and in the Z direction to insulate the conductive layers (word lines WL) 13 to 22 provided in the stacked body 101. The NANP strings NS are formed at the intersecting portions of the conductive layers 13 to 22 and the memory pillars MP.

The memory pillars MP include, for example, a block insulation film 31, a charge storage film 32, a tunnel insulation film 33, and a silicon single crystal layer 34 serving as a semiconductor layer. In particular, the block insulation film 31 is provided on the inner wall, of a memory hole in which the memory pillar MP is to be formed. The charge storage film 32 is provided on the inner wall of the block insulation film 31. The tunnel insulation film 33 is provided on the inner wall of the charge storage film 32. Finally, the silicon single crystal layer 34 is provided on the inner wall of the tunnel insulation film 33. The memory pillar MP may have a core insulation layer within the silicon single crystal layer 34.

In the memory pillar MP having such a structure, the intersecting portion of the memory pillar MP and the conductive layer 13 functions as a selection transistor ST2. The intersecting portions of the memory pillar MP and the conductive layers 14 to 21 function as memory transistors MT0 to MT7, respectively. The intersecting portion of the memory pillar MP and the conductive layer 22 functions as a selection transistor ST1. Hereinafter, the “memory transistor MT” denotes “each of memory transistors MT0 to MT7”.

The silicon single crystal layer 34 functions as a channel layer for the memory transistor MT and selection transistors ST1 and ST2.

The charge storage film 32 has a function of storing electric charge injected from the silicon single crystal layer 34 in the memory transistor MT. The charge storage film 32 includes, for example, a silicon nitride film.

When the charge is injected from the silicon single crystal layer 34 into the charge storage film 32, or when the charge stored in the charge storage film 32 is diffused into the silicon single crystal layer 34, the tunnel insulation film 33 functions as a potential barrier. The tunnel insulation film 33 includes, for example, a silicon oxide film.

The block insulation film 31 prevents the charge stored in the charge storage film 32 from diffusing into the conductive layers (word lines WL) 14 to 21. The block insulation film 31 includes, for example, a silicon oxide film and silicon nitride film.

A NAND string NS includes a selection transistor ST2, memory transistors MT0 to MT7, and a selection transistor ST1.

### [1-1-2] Cross-Section Structure of Semiconductor Memory Device

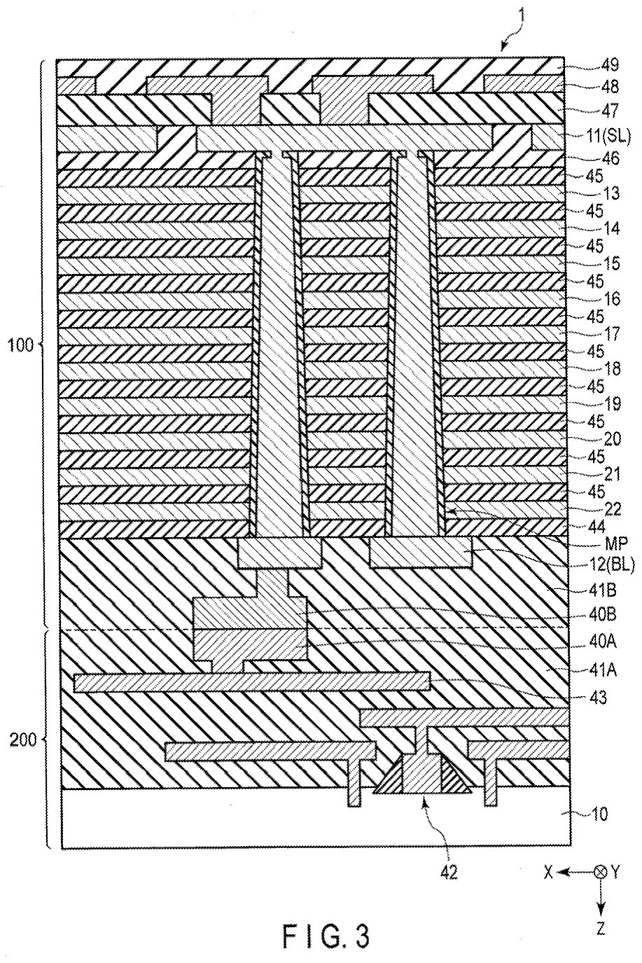

Next, the cross-section structure of the semiconductor memory device 1 according to the first embodiment will be described with reference to FIG. 3. FIG. 3 is a cross section of the semiconductor memory device according to the first embodiment, taken along the X direction. The structure is illustrated in FIG. 3 by flipping the structure of FIGS. 1 and 2 relative to the Z direction.

As illustrated in FIG. 3, a memory chip 100 is provided on the circuitry chip 200. That is, the circuitry chip 200 and the memory chip 100 are bonded to each other in such a manner that a conductive pad 40A and insulation layer 41A of the circuitry chip 200 face the conductive pad 40B and insulation layer 41B, respectively, of the memory chip 100.

The structure of the circuitry chip 200 will be described below. The circuitry chip 200 includes a peripheral circuit, for controlling writing, reading, and erasing or data with respect to the memory cells. The peripheral circuit includes a CMOS circuit 42 having an n-channel MOS transistor (hereinafter, an nMOS transistor) and p-channel MOS transistor (hereinafter, pMOS transistor). The nMOS transistor and pMOS transistor are formed on the semiconductor substrate, for example on the silicon substrate 10, and have a channel in the surface region of the silicon substrate 10.

The insulation layer 41A is provided on the silicon substrate 10. The CMOS circuit 42, a conductive layer 43, and the conductive pad 40A included in the peripheral circuit, are provided in the insulation layer 41A on the silicon substrate 10. The conductive layer 43 forms an interconnect, and may be coupled to the source, drain, or gate of the nMOS transistor and pMOS transistor.

The insulation layer 41A includes, for example, a silicon oxide layer. The conductive layer 43 includes, for example, a metal material such as tungsten (W), aluminum (Al), or copper (Cu). The conductive pad 40A includes, for example, a metal material such as copper (Cu).

Next, the structure of the memory chip 100 will be described. The conductive pad 40B is provided on the conductive pad 40A, and the insulation layer 41B is provided on the insulation layer 41A. A conductive layer (bit lines BL) 12 is provided in the insulation layer 41B. The conductive layer 12 is coupled to the conductive pad 40B.

The conductive pad 40B includes, for example, a metal material such as copper (Cu). The insulation layer 41B includes, for example, a silicon oxide layer. The conductive layer 12 includes, for example, a metal material such as tungsten (W), aluminum (Al), or copper (Cu).

The insulation layer 44 is provided on the conductive layer 12 and the insulation layer 41B. Furthermore, a plurality of conductive layers (select gate line SGD, word line3 WL, select gate line SGS) 22 to 13 and a plurality of insulation layers 43 are alternately arranged on the insulation layer 44. The contact plugs CP are omitted in this drawing. The conductive layers 22 to 13 include, for example, a metal material such as tungsten (W). The insulation layers 44 and 45 include, for example, silicon oxide layers.

An insulation layer 46 is provided on the insulation layer 45 that is provided on the conductive layer 13. A conductive layer (source line SL) 11 is provided in the insulation layer 46. An insulation layer 47 is provided on the conductive layer 11 and the insulation layer 46. A conductive layer 48 is provided on the insulation layer 47. The conductive layer 48 is coupled to the conductive layer 11 with a contact portion interposed therebetween, and functions as a source line SL, together with this conductive layer 11. Furthermore, an insulation layer 49 is provided on the conductive layer 48 and the insulation layer 47.

The insulation layers 46, 47, and 45 include, for example, silicon oxide layers. The conductive layer 11 includes an n+ silicon single crystal layer, to which impurities are added in high concentration. The conductive layer 48 forms an interconnect, and includes, for example, a metal material such as tungsten (W), aluminum (Al), or copper (Cu).

The memory pillar MP includes a columnar shape (e.g., circular column or elliptical column) that extends in the Z direction, and is provided in the conductive layers 22 to 13 and the insulation layers 45. The memory pillar MP extends from the surface of the conductive layer 12 through the insulation layer 44, the conductive layers 22 to 13, the insulation layers 45, and the insulation layer 46 to reach the surface of the conductive layer 11.

### [1-2] Method for Manufacturing Semiconductor Memory Device

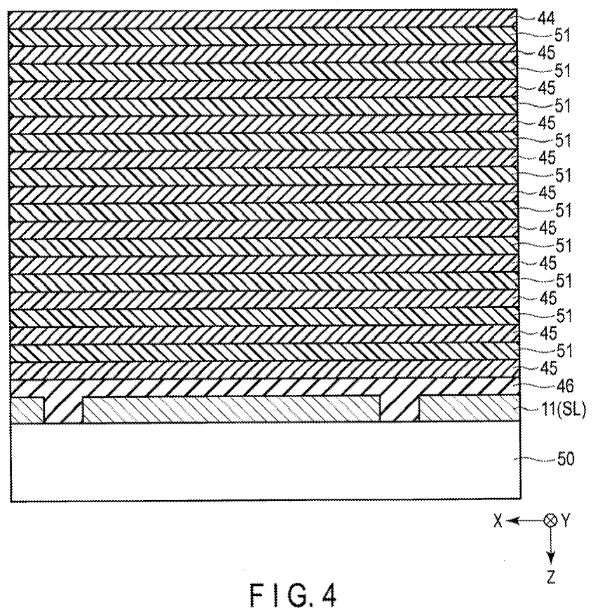

Next, the method for manufacturing a semiconductor memory device 1 according to the first embodiment will be explained with reference to FIGS. 3 to 14. FIGS. 4 to 14 are cross sections of a structure, representing processes of the method for manufacturing the semiconductor memory device according to the first embodiment. The structure is illustrated in FIGS. 4 to 12 and 15 to 21 by flipping the structure of FIG. 3 relative to the Z direction.

First, the method of manufacturing the memory chip 100 will be discussed. As illustrated in FIG. 4, an n+ silicon single crystal layer, to which impurities are added in high concentration, is deposited on the silicon substrate 50 by chemical vapor deposition (CVD) (alternatively by Atomic layer deposition (ALD)), and then the n+ silicon single crystal layer is etched by photolithography to form a conductive layer (n+ silicon single crystal layer) 11. Thereafter, an insulation layer A6 is formed on the conductive layer 11 and the silicon substrate 50. As a result, an element isolation/insulation layer (shallow trench isolation (STI)) is formed between the conductive layers 11. The insulation layer 46 includes, for example, a silicon oxide layer.

Next, a plurality of insulation layers 45 and a plurality of insulation layers 51 are alternately formed on the insulation layer 46. Furthermore, an insulation layer 44 is formed on the topmost insulation layer 51. The insulation layers 45 and 44 include, for example, silicon oxide layers, and the insulation layers 51 include, for example, silicon nitride layers.

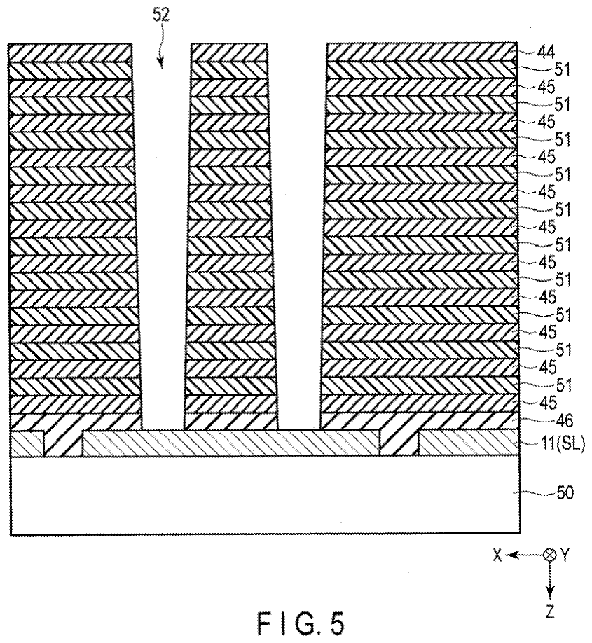

Next, as illustrated in FIG. 5, memory holes 52 are formed by RIE in the insulation layer 44, the insulation layers 51, the insulation layers 45, and the insulation layer 46. Each of the memory holes 52 extends from the surface of the insulation layer 44 to the surface of the conductive layer 11.

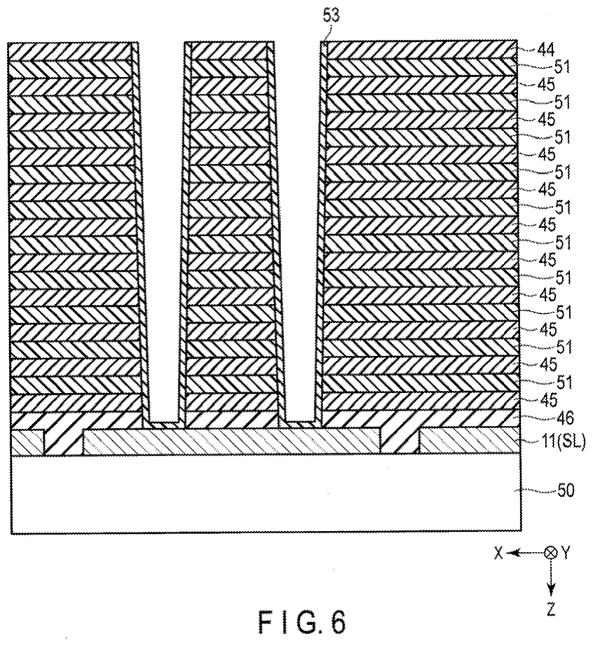

Thereafter, as illustrated in FIG. 6, a cell insulation film 53 is formed by CVD (or ALD) on the inner wall of the memory hole 52. The cell insulation film 53 includes the block, insulation film, charge storage film, and tunnel insulation film that have been discussed above. The block insulation film, charge storage film, and tunnel insulation film are formed in this order on the inner wall of the memory hole 52.

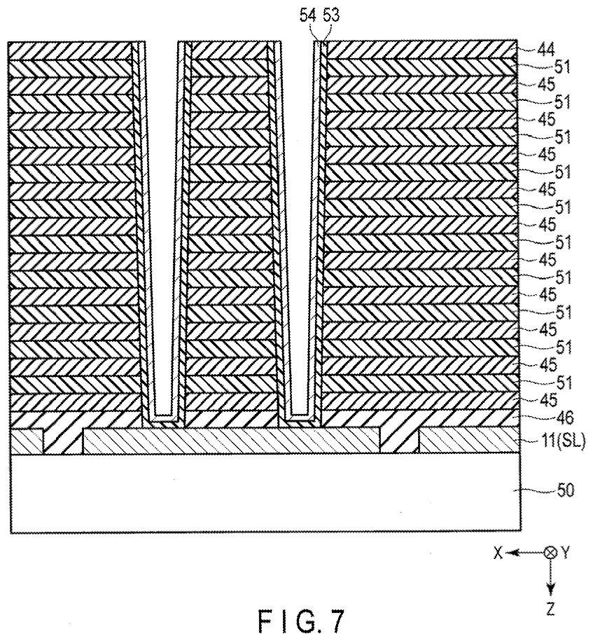

Next, as illustrated in FIG. 7, a sacrifice film 54 is formed by CVD (or ALD) on the cell insulation film 53 that is formed on the inner wall of the memory hole 52. The sacrifice film 54 includes, for example, an amorphous silicon film.

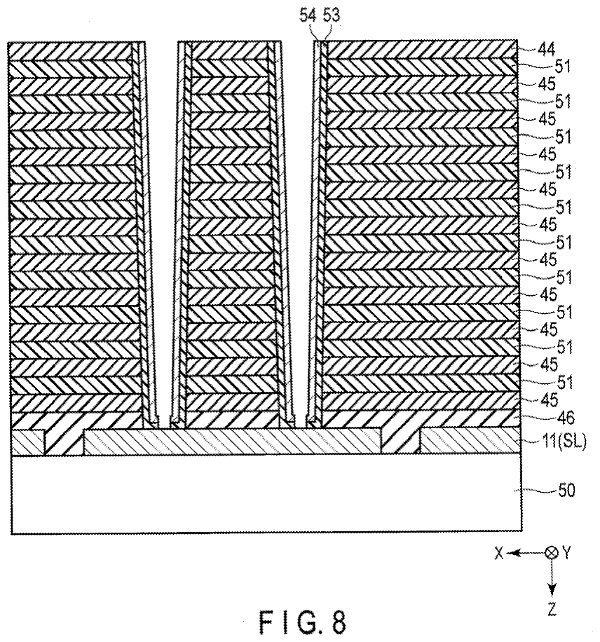

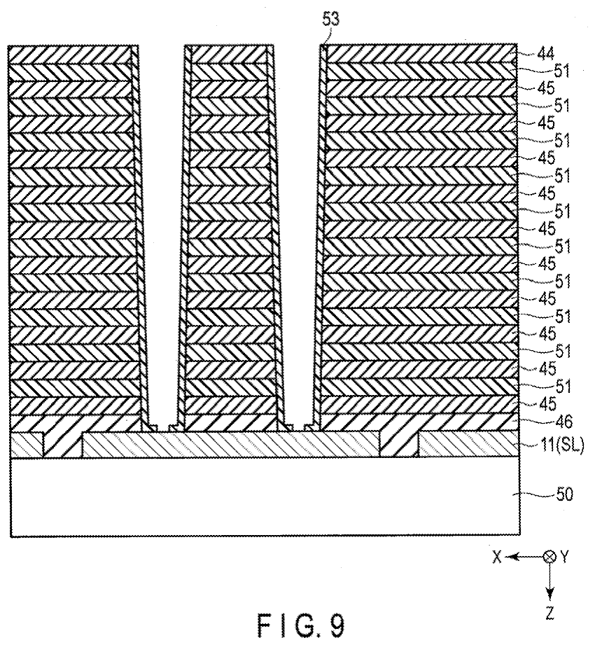

Next, as illustrated in FIG. 8, the sacrifice film 54 and the cell insulation film 53 are removed by FIE from the bottom surface of the memory hole 52 so as to expose the surface of the conductive layer 11. Then, as illustrated in FIG. 9, the sacrifice film 54 on the cell insulation film 53 in the memory hole 52 is removed.

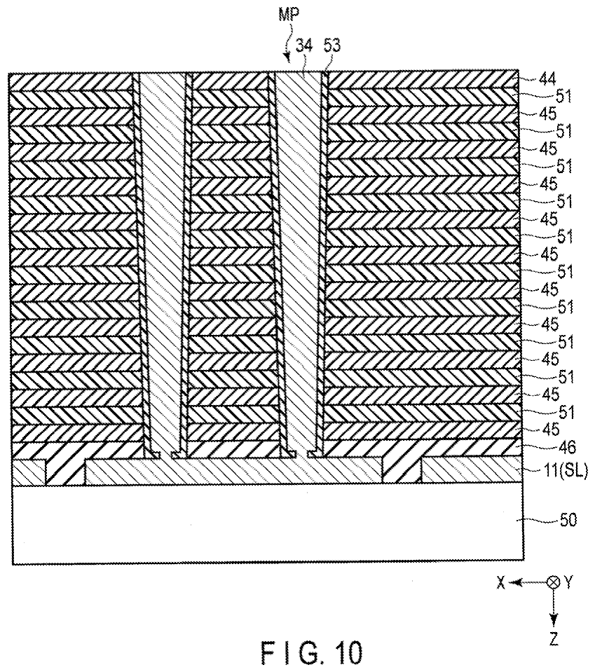

Thereafter, silicon is grown by epitaxial growth from the conductive layer (n+ silicon single crystal layer) 11 on the bottom surface of the memory hole 52 so that a silicon single crystal layer 34 can be formed in the memory hole 52, as shown in FIG. 10. As a result, a memory pillar MP that includes the cell insulation film 53 and the silicon single crystal layer 34 is formed in the memory hole 52.

Next, slits (not shown) are formed by RIE in the insulation layer 44, the insulation layers 51, the insulation layers 45, and the insulation layer 46. The slits extend from the surface of the insulation layer 44 to the surface of the conductive layer 11. Thereafter, the insulation layers (silicon nitride layers) 51 are removed by wet etching using, tor example, a phosphoric acid solution introduced through the slits. On the other hand, the insulation layers 44, 45, and 46 will remain, without being removed. As a result, gaps are formed between the insulation layers 45.

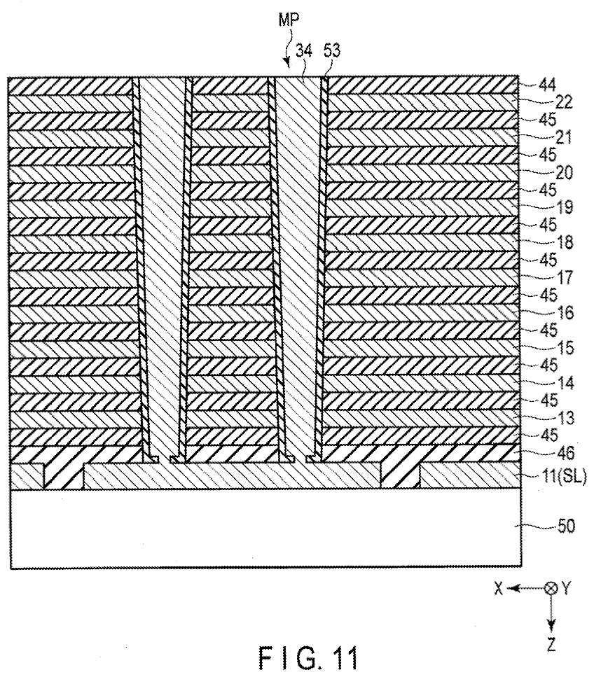

Next, as illustrated in FIG. 11, the conductive layers (select gate line SGS, word lines WL, and select gate line SGD) 13 to 22 are formed in the gaps by CVD (or ALD). Thus, the conductive layers 13 to 22 are formed in a manner to fill the gaps between the insulation layers 45.

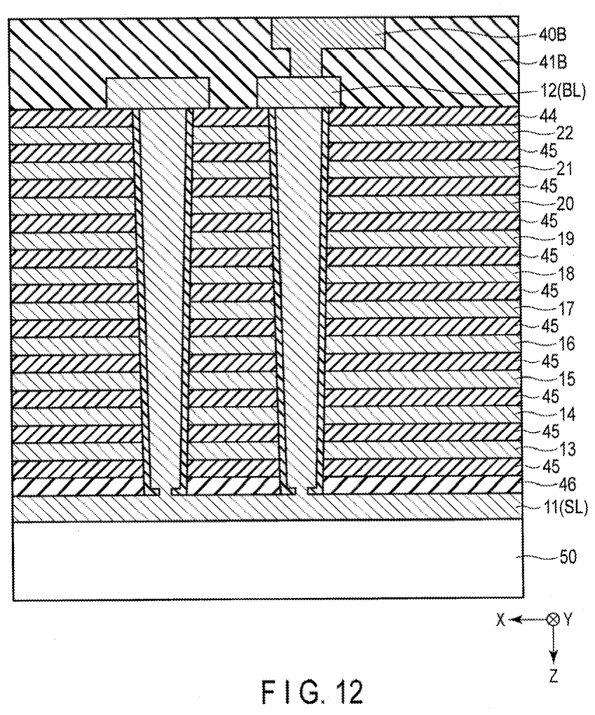

Thereafter, as illustrated in FIG. 12, the conductive layers (bit lines EL) 12 are formed on the memory pillars MP. Then, an insulation layer 41B is formed on the conductive layers 12 and the insulation layer 44. Furthermore, a conductive pad 40B is formed in the insulation layer 41B. The conductive pad 40B is coupled to the conductive layers 12. The surfaces of the conductive pad 40B and insulation layer 41B are planarized, and the surface of the conductive pad 40B is exposed.

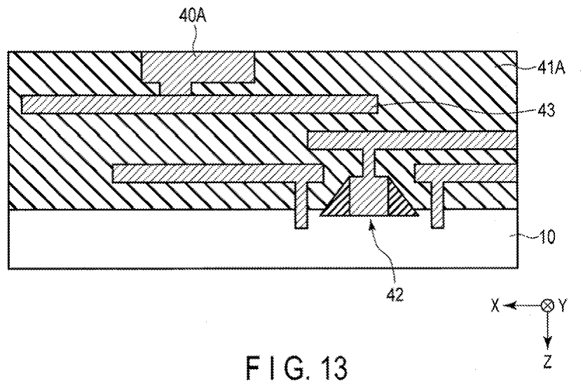

Next, the method of manufacturing the circuitry chip 200 will be briefly explained below. As illustrated in FIG. 13, the CMOS circuit 42 including an nMOS transistor ana a pMOS translator is formed on a semiconductor substrate such a3 the silicon substrate 10. Thereafter, the insulation layer 41A and multi-layered conductive layers 43 are formed above the silicon substrate 10. On this conductive layer 43, a conductive pad 40A is formed. The surfaces of the conductive pad 40A and the insulation layer 41A are planarized, and the surface of the conductive pad 40A is exposed.

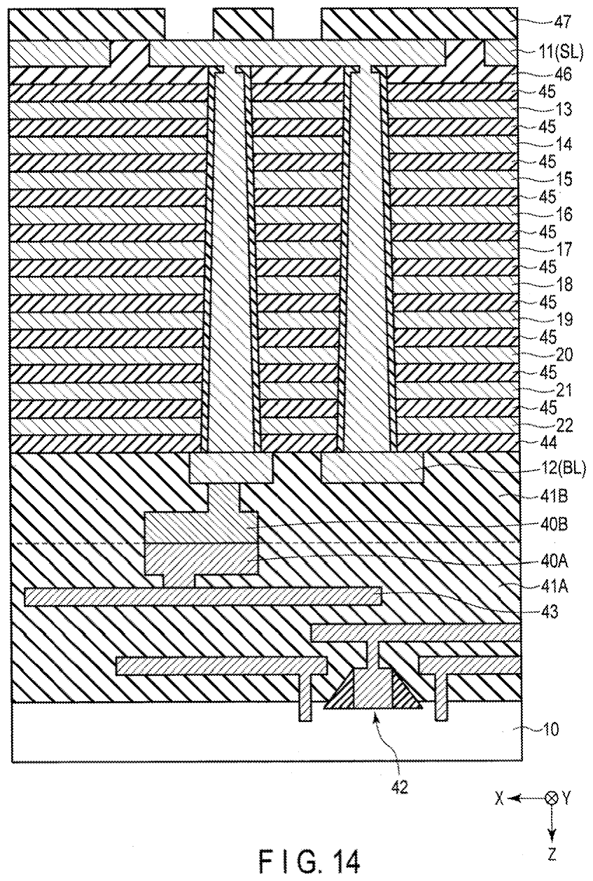

Then, as illustrated in FIG. 14, the circuitry chip 200 and the memory chip 100 are bonded to each other in a manner that the conductive pad 40A and the conductive pad 40B face each other and the insulation layer 41A and the insulation layer 4tB face each other. That is, the memory chip 100 in FIG. 12 is inverted relative to the Z direction, and the inverted memory chip 100 is bonded onto the circuitry chip 200 in FIG. 13. In this manner, the conductive pad 40A and the conductive pad 40B are bonded to each other, and the conductive pad 40A and the conductive pad 40B are electrically coupled to each other.

The conductive pad 40A and the conductive pad 40B contain, for example, copper. This bonds the conductive pad 40A and the conductive pad 40B to each other, forming an integral body of the conductive pads 40A and 40B as illustrated in FIG. 14. As a result, the conductive layer 12 and memory pillars MB of the memory chip 100 and the conductive layer 43 and CMOS circuit 42 of the circuitry chip 200 are electrically coupled tc each other via the conductive pads 40A and 40B.

After bonding the circuitry chip 200 to the memory chip 100, the silicon substrate 50 of the memory chip 100 is polished and removed, for example, by chemical mechanical polishing (CMP) or with a grinder. The silicon substrate 50 may be removed by wet etching using fluoro-nitric acid. Thereafter, the insulation layer 47 is formed on the surface from which the silicon substrate 50 has been removed, or in other words, on the conductive layer 11 and the insulation layer 46. Furthermore, holes for contact are formed in the insulation layer 47 by photolithography.

As illustrated in FIG. 3, a conductive layer is deposited by CVD (or ALD) on the insulation layer 47 and in the contact holes. This conductive layer, is patterned by photolithography to form a conductive layer 48. Then, the insulation layer 49 is formed on the conductive layer 48 and the insulation layer 47. The method for manufacturing the semiconductor memory device 1 is thereby completed.

The above processing steps are realized on a wafer having memory chips 200 and a wafer having circuitry chips 200, and at the end of the process, the resultant structure is cut into chips for the semiconductor memory devices 1.

Specifically, the wafer having the circuitry chips 200 and the wafer having the memory chips 100 are bonded to each other, as discussed above, in a manner that the conductive pads 40A and 40B face each other, and the insulation layers 41A and 41B face each other. Thereafter, the silicon substrate 50 of the wafer having the memory chips 100 is polished and removed by CMP or with a grinder. Furthermore, the conductive layer 48 and the insulation layers 47 and 49 are formed on the conductive layer 11. Then, the bonded two wafers are cut into chips for the semiconductor memory devices 1.

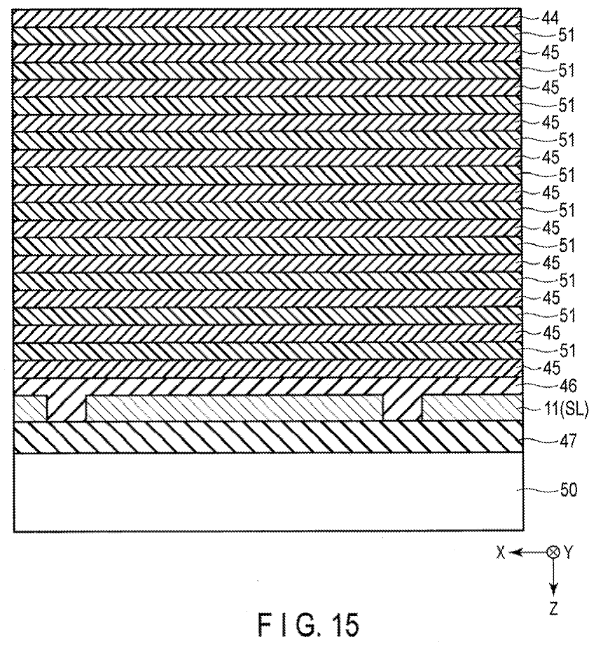

Next, a modified example of the method for manufacturing the semiconductor memory device 1 will be explained with reference to FIGS. 15, 14 and 3. FIG. 15 is a cross section of the structure, representing the process of the modified manufacturing method.

According to the first embodiment, the conductive layer 11 is formed on the silicon substrate 50. In this modified example, a silicon-on-insulator (SOI) substrate is employed. That is, as illustrated in FIG. 15, a substrate in which a conductive layer 11 is formed on the silicon substrate 50 with an insulation layer 47 interposed therebetween is prepared. After this step, the same processing steps as in the first embodiment are performed, up until the step of bonding the circuitry chip 200 and memory chip 100.

After bonding the circuitry chip 200 to the memory chip 100, the silicon substrate 50 of the memory chip 100 is polished and removed, for example, by CMP or with a grinder. The insulation layer 47 appears on the surface from which the silicon substrate 50 is removed. Thereafter, as illustrated in FIG. 14, contact holes are formed in the insulation layer 47, and the conductive layer 48 is further formed, as illustrated in FIG. 3. The step for forming the insulation layer 49 is the same as the first embodiment.

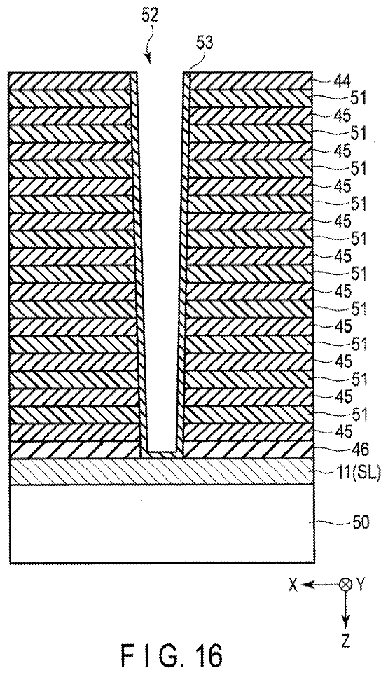

As mentioned above, the memory pillar MP may have a core insulation layer within the silicon single crystal layer 34. The method for manufacturing this structure will be discussed with reference to FIGS. 16 to 21.

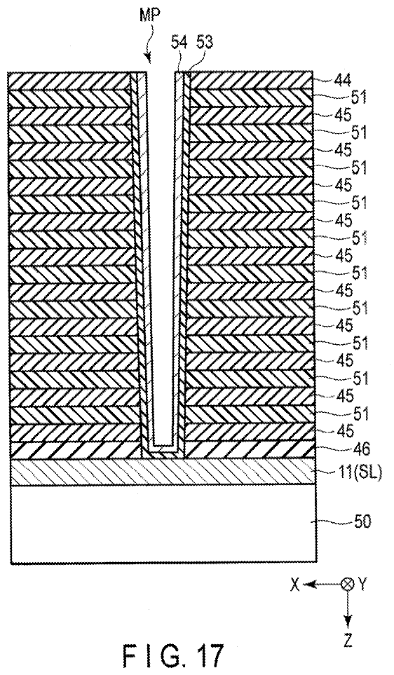

As illustrated in FIG. 16, a cell insulation film 53 is formed on the inner wall of the memory hole 52. Furthermore, as illustrated in FIG. 17, a sacrifice film 54 is formed on the inner wall of this cell insulation film 53. The sacrifice film 54 includes, for example, an amorphous silicon film.

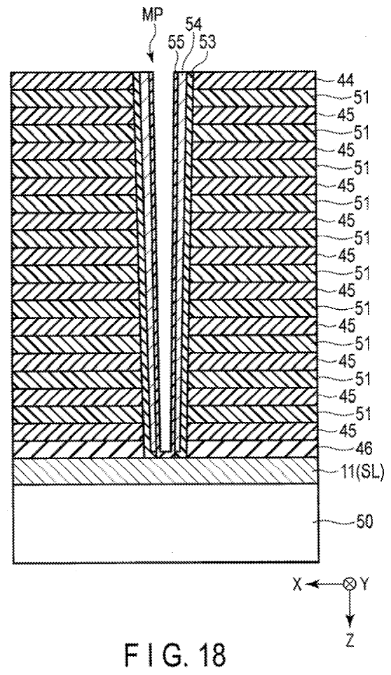

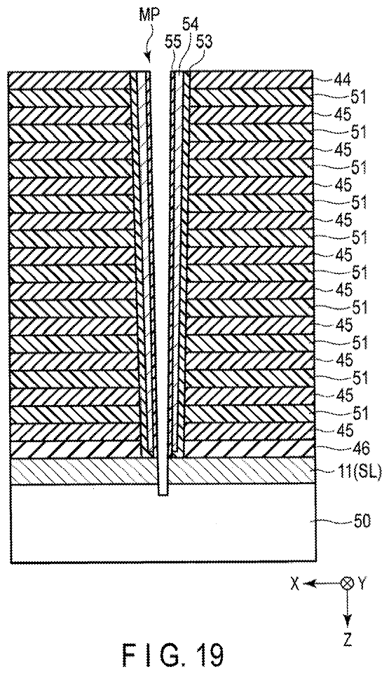

Thereafter, as illustrated in FIG. 18, the sacrifice film 54 and the cell insulation film 53 are removed by PIE from the bottom surface of the memory hole 52. A sacrifice film 55 is formed on the sacrifice film 54 in the memory hole 52. The sacrifice film 55 includes, for example, an amorphous silicon film. Thereafter, as illustrated in FIG. 19, the sacrifice film 55 is removed by RIE from the bottom surface of the memory hole 52. The hole is further processed so as to reach the silicon substrate 50.

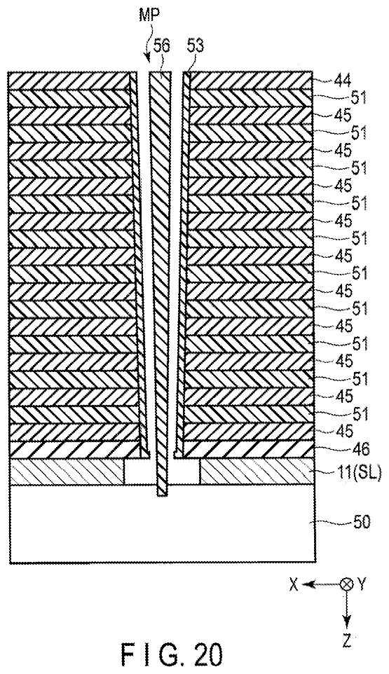

Next, as illustrated in FIG. 20, a core insulation layer 56 is embedded in the memory hole 52. The core insulation layer 56 is embedded so as to extend into the silicon substrate 30. In this manner, the core insulation layer 56 can be prevented from collapsing. The core insulation layer 56 includes, for example, a silicon oxide layer. The sacrifice films 54 and 55 are removed from the memory hole 52 so that a gap can be formed between the cell insulation film 53 and the core insulation layer 56.

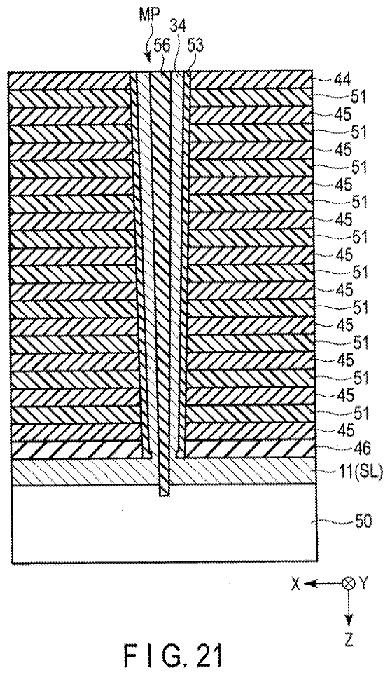

Thereafter, as illustrated in FIG. 21, silicon is grown by epitaxial growth from the conductive layer (n+ silicon single crystal layer) 11 on the bottom surface of the memory hole 52, thereby forming a silicon single crystal layer 34 between the cell insulation film 53 and the core insulation layer 56. In this manner, the memory pillar HP, which includes the cell insulation film 53, the silicon single crystal layer 34 and the core insulation layer 56, is formed in the memory hole 52.

### [1-3] Effects of First Embodiment

The first embodiment offers a semiconductor memory device in which the on-state current of a memory cell can be increased.

The effect of the present embodiment will be discussed in detail below. As a three-dimensional memory goes through generations of evolution, the height of the memory pillar has increased, which increases the resistance of the channel in the memory pillar. When polycrystalline silicon .is used as a channel, the channel mobility is desired to be improved in order to ensure the on-state current. In the structure adopting a polycrystalline silicon layer, the mobility may be improved by increasing the size of silicon crystal grains and lowering the density of the crystal grain boundaries, which often becomes the cause of the scattering of carriers. In an attempt to lower the crystal grain boundary density, however, the grain boundaries immediately below the memory cells may come to vary, which may result in variation in the threshold voltage among the memory cells.

According to the present embodiment, silicon single crystal is adopted tor the channel in the memory pillar so that the silicon crystalline grain boundaries can be reduced, as a result of which the mobility can be improved. This can increase the on-state current of the memory cell. Furthermore, without the crystal grain boundary of the silicon, variation in grain boundary density can also be suppressed. As a result, variation in threshold voltages among the memory cells can be suppressed. In other words, the present embodiment can achieve both increase in the on-state current of the memory cells and suppression of variation in the threshold voltage among memory cells.

Furthermore, because a memory chip, in which silicon single crystal, is already formed, is bonded to a circuitry chip, the step of forming a silicon single crystal layer by epitaxial growth in the memory chip will not cause any damage to the circuitry chip. That is, if a heat load is applied to the CMOS circuit in the peripheral circuit due to the high-temperature heat used for the epitaxial growth of the silicon single crystal, the impurities in the CMOS circuit may be diffused, as a result of which the circuit characteristics may be lowered. By separately preparing a memory chip in which a memory cell array is formed and a circuitry chip in which peripheral circuit is formed, and then by bonding these chips, the circuit characteristics of the CMOS circuit can be prevented from being lowered. In addition, in the modification example of the manufacturing method using a SOI substrate, an insulation layer is already provided on the conductive layer (source line SL) when removing the silicon substrate from the memory chip after bonding the circuitry chip and the memory chip. Thus, there is no need to prepare an additional insulation layer. Thus, the manufacturing method can be simplified.

### [2] SECOND EMBODIMENT

A semiconductor memory device according to a second embodiment will be explained. According to the first embodiment, the conductive layer (n+ silicon single crystal layer) 11 is provided as a source line 3L. According to the second embodiment, a metal silicide layer is provided, in addition to the conductive layer 11, as a source line SL. The explanation of the second embodiment will focus mainly on the structure different from the first embodiment. The rest of the structure is the same as in the first embodiment.

### [2-1] Cross-Section Structure of Semiconductor Memory Device

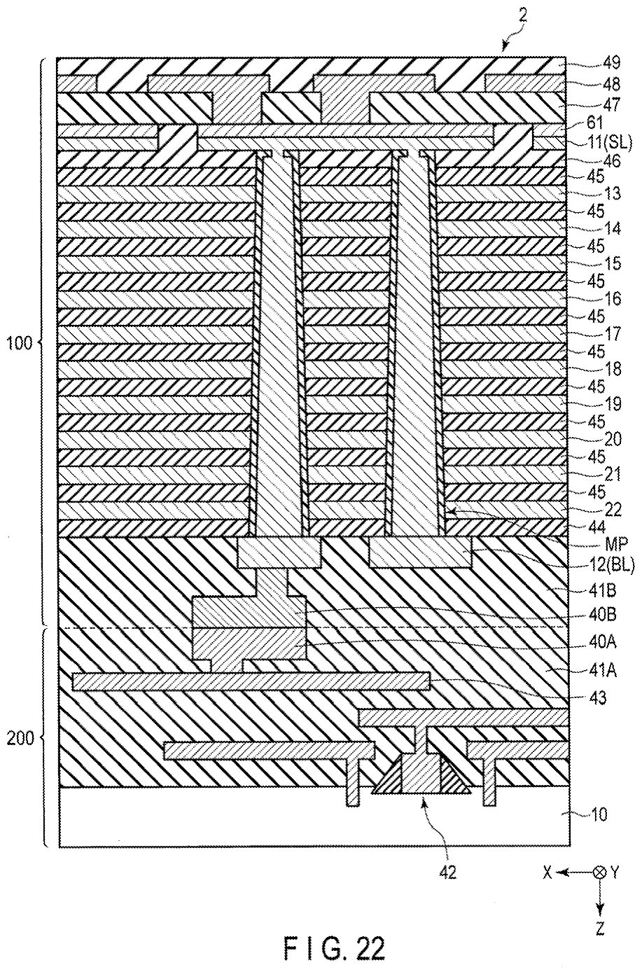

The cross-section structure of a semiconductor memory device 2 according to the second embodiment will be explained with reference to FIG. 22. FIG. 22 is a cross section of the semiconductor memory device according to the second embodiment, taken along the X direction. The structure is illustrated in FIG. 22 by inverting the structure of FIGS. 1 and 2 relative to the Z direction.

An insulation layer 46 is provided on the insulation layers 45 that is provided on the conductive layer (source-side select gate line SGS) 13. A conductive layer (source line SL) 11 is provided in the insulation layer 46, and a metal silicide layer 61 is provided on the conductive layer 11. An insulation layer 47 is provided on the metal silicide layer 61 and the insulation layer 46. A conductive layer 48 is provided on the insulation layer 47. This conductive layer 48 is coupled to the metal silicide layer 61 via a contact portion, and functions as a source line SL, together with the conductive layer 11 and the metal silicide layer 61. Furthermore, an insulation layer 49 is provided on the conductive layer 48 and the insulation layer 47. The rest of the structure is the same as in Che first embodiment.

### [2-2] Method for Manufacturing Semiconductor Memory Device

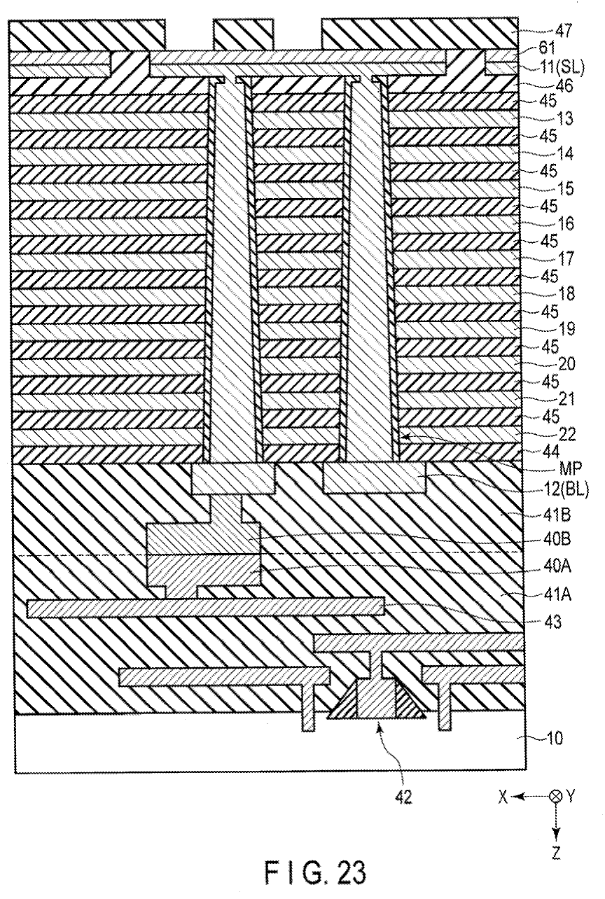

Next, the method for manufacturing the semiconductor memory device 2 according to the second embodiment will be explained with reference to FIGS, 22 and 23. FIG. 23 is a cross section of the structure, representing the process of the manufacturing method according to the second embodiment.

After bonding the circuitry chip 200 to the memory chip 100, the silicon substrate 50 of the memory chip 100 is polished and removed, for example, by CMP or with a grinder. As a result, the conductive layer 11 is exposed on the surface from which the silicon substrate 50 is removed. Thereafter, a metal material such as nickel (Ni), cobalt (Co), or titanium (Ti) is prepared or. the conductive layer 11, and is subjected to a heat treatment. As a result, as illustrated in FIG. 23, the metal silicide layer 61 is formed on the conductive layer 11. Furthermore, the insulation layer 47 is formed on the metal silicide layer 61 and the insulation layer 46. Then, contact holes are formed in the insulation layer 47 by photolithography.

As illustrated in FIG. 22, a conductive layer is deposited by CVD (or ALD) on the insulation layer 47 and in the contact holes. This conductive layer is patterned by photolithography to form the conductive layer 48. Then, the insulation layer 49 is formed on the conductive layer 48 and the insulation layer 47. The method for manufacturing the semiconductor memory device 2 is thereby completed.

### [2-3] Effects of Second Embodiment

Similarly to the Hirst embodiment, the on-state current of the memory cells can be increased, while variations in the threshold voltage among memory cells can be suppressed according to the second embodiment. In addition, according to the second embodiment, a stacked structure of a silicon single crystal layer and a metal si.iici.de layer is provided as a source line SL so that the electric resistance of the source line SL can be lowered. Other effects are the same as in the first embodiment.

### [3] OTHER MODIFICATION EXAMPLES

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

What is claimed is:

1. A method of manufacturing a semiconductor memory device comprising:
forming a first silicon single crystal layer on a first substrate;
forming a stacked film in which a plurality of first films and a plurality of second films are alternately stacked above the first silicon single crystal layer;
forming a hole that passes through the stacked film along a stacking direction of the stacked film and reaches the first silicon single crystal layer;
forming a cell insulation layer on an inner wall of the hole; and
forming a second silicon single crystal layer on an inner wall of the cell insulation layer in the hole;
forming a first conductive pad above the second silicon single crystal layer;
forming a CMOS circuit including an n-channel MOS transistor and a p-channei MOS transistor on a second substrate;
forming a second conductive pad above the CMOS circuit; and
bonding the first substrate and the second substrate to each other such that the first conductive pad faces the second conductive pad.

2. The method according to claim 1,
wherein the forming the second silicon single crystal layer includes growing the first silicon single crystal layer on a bottom surface of the hole by epitaxial growth to provide the second silicon single crystal layer in the hole.

3. The method according to claim 1, further comprising:
after bonding the first substrate and the second substrate to each other,
polishing a surface of the first substrate on which the first silicon single crystal layer is not formed to expose the first silicon single crystal layer;
forming a metal layer on the exposed first silicon single crystal layer; and
forming a metal silicide layer by reacting the first silicon single crystal layer with the metal layer.
